(19) United States
(12) Patent Application Publication
(10) Pub. No.: US 2017/0044340 A1
(43) Pub. Date: Feb. 16, 2017

(54) SELF-CLEANSING SUPER-HYDROPHOBIC POLYMERIC MATERIALS FOR ANTI-SOILING

(71) Applicant: SABIC Global Technologies B.V., Bergen op Zoom (NL)

(72) Inventors: Abdiaziz A. Farah, Thuwal (SA); Steven M. Gasworth, Wixom, MI (US)

(21) Appl. No.: 15/303,912

(22) PCT Filed: May 13, 2015
(86) PCT No.: PCT/US2015/030565

§ 371 Date: Oct. 13, 2016

Related U.S. Application Data
(60) Provisional application No. 62/003,309, filed on May 27, 2014.

(51) Int. Cl. C08J 7/12; H01L 31/18; H01L 31/049; C08J 7/04

(52) U.S. Cl. CPC C08J 7/123; C08J 7/042; C08J 7/12; C08J 7/126; H01L 31/18; H01L 31/049; C08J 2369/00; C08J 2483/04

(57) ABSTRACT

Disclosed are optically transparent super-hydrophobic materials, and methods for making and using the same, that can include an optically transparent polymeric layer having a first surface and an opposing second surface. At least a portion of the first surface has been plasma-treated with oxygen and a fluorine containing compound. The treated surface includes nano- or micro-structures that are etched into the first surface and that are chemically modified with the fluorine containing compound. The nano- or micro-structures have a height to width aspect ratio of greater than 1, and a water contact angle of at least 150°. The optically transparent polymeric layer retains its optical transparency after said plasma-treatment. Due to their optical transparency, chemical and thermal robustness, weatherability, and self-cleaning performance, the super-hydrophobic materials disclosed are useful in high performing solar cell units in harsh semi-arid environments.

### CROSS REFERENCE TO RELATED APPLICATIONS

This application claims benefit to U.S. Provisional Patent Application No. 62/003,309 titled “SELF-CLEANSING SUPER-HYDROPHOBIC POLYMERIC MATERIALS FOR ANTI-SOILING” filed May 27, 2014. The entire contents of the referenced patent application are incorporated into the present application by reference.

### BACKGROUND OF THE INVENTION

1. Field of the Invention

The invention generally concerns super-hydrophobic materials that have self-cleansing or antifouling properties. These materials can be obtained by plasma treating optically transparent polymeric materials (e.g., silicone hard-coated polycarbonates or SHC-PCs). The plasma treatment can impart a super-hydrophobic surface to the material while maintaining the material's spectral transmittance profile. Articles of manufacture that are prone to soiling (e.g., solar panels) can benefit from the super-hydrophobic materials of the present invention.

2. Description of Related Art

A solar panel is typically made up of a solar cell that includes photoactive layer(s), electrodes, and reflective backing. The cell is protected by an outer-cover, which has to have good optical transparency so as to allow sunlight to pass through to the photoactive layer(s). It is also beneficial if the outer-cover has good durability characteristics such as being heat resistant and impact resistant. Currently, glass is the preferred material that is used for the outer-cover.

Glass covers are prone to soiling, especially in semi-arid environments. Soiling can limit the efficiency of solar panels due to airborne dust or particle accumulation on the glass surface, which can decrease light transmission to the active layer(s). This can result in decreased panel output power. This situation is exacerbated in less accessible, water scarce environments such as deserts, that have a high occurrence of dust storms that introduce particles of different origins, sizes, and compositions to solar panels. While various types of surface treatments and coatings can be applied to the glass covers to impart self-cleansing properties, such treatment can be costly, prone to degradation, and ultimately ineffective over prolonged periods of use.

Organic polymeric materials can offer significant advantages when compared to glass. For example, the vast number of polymers to select from and the manufacturing processes for preparing a polymeric layer can favor polymeric materials over glass. Additionally, polymeric materials typically have significantly lower densities when compared with glass, which facilitates transportation, handling, installation, and reduces load on solar panel support structures. Also, such polymeric materials have stronger impact resistance properties when compared to glass, which makes the polymeric materials less prone to breakage. An issue with the use of polymers in outside applications such as protective covers for solar panels, however, is polymer degradation (e.g., embrittlement) and yellowing or loss of transparency under long-term exposure to sun. Still further, optically transparent polymers (e.g., polycarbonates and blends thereof) are known to be sensitive when subjected to conventional treatments that are used to impart self-cleansing properties. For instance, the optical transparency of the polymer can be negatively affected by such treatments. Without such treatments, however, the polymeric material is especially prone to soiling.

While some attempts have been made to produce polymeric materials that have self-cleansing surfaces, these attempts either require the use of inorganic additives that can negatively affect the transparency of the material or require complicated and convoluted processing steps. Still further, the issue of the durability of the polymeric material at elevated temperatures (e.g., 60° C. or greater) is not addressed. Therefore, the use of polymeric materials as protective layers in solar panels currently has limited value.

### SUMMARY OF THE INVENTION

The present invention offers a solution to the aforementioned problems associated with the use of polymeric materials as protective covers for devices that require sufficient durability, optical transparency, and self-cleansing properties (e.g., solar panels). The solution is premised on subjecting optically transparent polymeric materials to processing steps that impart self-cleansing properties to the surfaces of such materials. Importantly, the processing steps do not negatively affect the spectral profile of the material. In particular, it was discovered that plasma treating polymeric materials with oxygen and fluorine-containing compounds results in treated surfaces that have water contact angles equal to or greater than 150° (i.e., super-hydrophobic surfaces are produced), while also maintaining their optical transparency. Without wishing to be bound by theory, it is believed that plasma treatment with oxygen produces nano- or micro-structures that are etched into the polymeric material, which increases the surface area of the treated surface. Plasma treatment with fluorine-containing compounds then imparts the super-hydrophobic effect, as the fluorine-containing compounds chemically bind to the nano- or micro-structures. The combined effect is an increased amount of hydrophobic compounds (i.e., fluorine containing material) on the surface of the polymeric material, thereby resulting in water contact angles equal to or greater than 150°. It is believed that the form and/or scale of the nano- or microstructures having a height to width aspect ratios of greater than 1 can help preserve the transmittance spectrum of the polymeric material. Even further, when the polymeric material is coated with a functional coating (e.g., abrasion or weather resistant coatings such as silicone hard-coat coatings (i.e. siloxane-based coatings)) before plasma treatment, the properties of the functional coating (e.g., heat resistance, ultra-violet absorbing properties, etc.) are also retained by using the plasma treatment of the present invention. Notably, the optical transparency, chemical and thermal robustness and suitability for out-door applications of the super-hydrophobic materials of the present invention provide a solution to the problems facing current technologies. The solution provides a self-cleaning over coat film for high performing solar cell units in harsh semi-arid regions.

In one aspect of the present invention, there is disclosed an optically transparent super-hydrophobic material comprising an optically transparent polymeric layer having a first surface and an opposing second surface, wherein at least a portion of the first surface has been plasma-treated with oxygen and a fluorine containing compound. The treated surface can include nano- or micro-structures that are etched into the first surface and that are chemically modified with the fluorine containing compound, wherein the nano- or micro-structures have a height to width aspect ratio of greater than 1, and a water contact angle of at least 150°, 155°, 160°, 165°, 170°, 175°, or more. In preferred aspects, the water contact angle is at least 150° to 175°, or at least 150° to 170°. In certain aspects, a specific water contact angle can be achieved by selecting the appropriate processing conditions (e.g., power used, exposure times to oxygen and fluorine containing compounds, type of gases used in the treatment processes, etc.). Thus, specific water contact angles such as 150, 151, 152, 153, 154, 155, 156, 157, 158, 159, 160, 161, 162, 163, 164, 165, 166, 167, 168, 169, 170, 171, 172, 173, 174, 175, 176, 177, 178, or 179 can be obtained by the processes of the present invention. Additionally, the surface can also have a water rolling angle of <10° or a hysteresis angle of <10° or both. These angles can also be modified or tuned as desired by selecting the appropriate processing conditions (e.g., power used, exposure times to oxygen and fluorine containing compounds, type of gases used in the treatment processes, etc.). By way of example only, water rolling angles of 9°, 8°, 7°, 6°, 5°, 4°, 3°, 2°, or 1° or less can be achieved. Hysteresis angles of 9°, 8°, 7°, 6°, 5°, 4°, 3°, 2°, or 1° or less can be achieved. Still further, the surface morphology of the optically transparent super-hydrophobic material can be modified or tuned as desired by selecting or varying any one of the following processing conditions: plasma treatment times, amount of power used, type of plasma used, temperature of the plasmas; and/or fluorine containing compound used. By way of example, the process conditions can be such that nanostructures are obtained at the exclusion of micro-structures, or micro-structures are obtained at the exclusion of nanostructures, or both nano- and microstructures are obtained, or the ratio of nanostructures to microstructures present on the material can be increased or decreased as desired. Non-limiting examples of nano- and microstructures include nanopillars, micropillars, nanospheres, microspheres, irregular shapes, etc. Also, the optically transparent polymeric layer retains its optical transparency after said plasma-treatment. By way of example, the light transmission value in the visible spectrum (400 nm to 700 nm) of the transparent polymeric layer pre- and post-plasma treatment does not vary by more than 10%, or by more than 5%, or by more than 4, 3, 2, or 1%. In some instance, the nano- or micro-structures on the treated surface of the polymeric layer can be created by the plasma treatment in that such structures are not present prior to said plasma treatment. Similarly, and in some instances, the water contact angle of the first surface can be less than 150° prior to said plasma-treatment and at least 150° post-plasma treatment. In preferred instances, the polymeric layer comprises polycarbonate or polycarbonate blends. However, other transparent polymers can be used in the context of the present invention with or in lieu of polycarbonate. Non-limiting examples of such additional polymers include polyethylene terephthalates, polyolefins, polystyrenes, poly(methyl)methacrylates, polyacrylonitriles, poly(vinylacetates), poly(vinyl alcohols), chlorine-containing polymers, polyoxymethylenes, polyamides, polyimides, polyurethanes, amino-epoxy resins, polyesters, or combinations or blends thereof. In some particular embodiments, the first or treated surface of the polymeric layer can have a functional coating (e.g., abrasion-resistant or weather resistant coatings), and the functional coating retains its functional properties after said plasma treatment. The functional coating can be present on the surface prior to plasma treatment, such that the nano- or micro-structures are etched into the coating, etched into the coating and polymer, or are etched in the polymer. The functional coating can have abrasion-resistant properties, ultra-violet absorbing properties, etc. In a preferred aspect, the functional coating can be a silicone hardcoat that is capable of absorbing ultra-violet light. Non-limiting examples of silicone hardcoats are provided throughout the specification and incorporated into this section by reference. A non-limiting example of such a coating is an aqueous/organic solvent silicone dispersion containing colloidal silica and a partial condensate of at least one organoalkoxysilane (e.g., AS4010, which is a partial condensate of methyltrimethoxysilane, colloidal silica, and silylated dibenzoresorcinol with isopropanol and n-butanol as co-solvents, available from Momentive Performance Materials). The fluorine containing compounds that can be used in the plasma treatment can be any such compounds that have hydrophobic properties. A non-limiting example of a class of such compounds is organofluorines. In one instance, the organofluorine can be a fluorocarbon, non-limiting examples of which include CF₄, C₂F₄, C₂F₆, C₃F₆, C₄F₈, or any combination thereof. In one aspect, the fluorocarbon is C₄F₈. In particular instances, covalent bonds can be formed between the nano- or micro-structures and individual fluorine containing compounds. The super-hydrophobic surface can be created by first treating the surface with plasma comprising oxygen followed by treating the surface with plasma comprising the fluorine containing compound. In other aspects, the plasma can include a mixture of oxygen and a fluorine containing compound. The morphology of the treated surface can be such that the nano- or micro-structures have a width or height or both in the range between about 10 nm to 5000 nm or 10 nm to 4000 nm or 10 nm to 3000 nm or 10 nm to 2000 nm or 10 nm to 1000 nm or 10 nm to 900 nm, or 10 nm to 800 nm or 10 nm to 700 nm or 10 nm to 600 nm or 10 nm to 500 nm or 10 nm to 400 nm or 10 nm to 300 nm or 10 nm to 200 nm or 10 to 100 nm. Similarly, the spacing between two adjacent nano- or micro-structures can range between about 10 nm to 5000 nm or 10 nm to 4000 nm or 10 nm to 3000 nm or 10 nm to 2000 nm or 10 nm to 1000 nm or 10 nm to 900 nm, or 10 nm to 800 nm or 10 nm to 700 nm or 10 nm to 600 nm or 10 nm to 500 nm or 10 nm to 400 nm or 10 nm to 300 nm or 10 nm to 200 nm or 10 nm to 100 nm. By “nano-structure,” it is meant that at least one dimension of the structure is equal to or less than 100 nm (e.g., one dimension is 1 to 100 nm in size). By “micro-structure,” it is meant that at least one dimension of the structure is greater than 100 nm (i.e., 0.1 μm) (e.g., 100 nm up to 5000 nm (i.e. 5 μm)) and in which no dimension of the structure is 0.1 μm or smaller. In some aspects, the spacing between two adjacent nano- or micro-structures can be greater than the width of a single nano- or micro-structure. The optically transparent material can be disposed on a substrate or comprised in an article of manufacture. In particular embodiments, the material can be the outermost surface of the substrate or article of manufacture such that the treated surface provides self-cleansing or antifouling properties to the substrate or article of manufacture. By way of example, the article of manufacture can be a photovoltaic cell or solar panel, and the super-hydrophobic material can be used as the outermost surface of the protective cover. In this sense, the super-hydrophobic material can be a replacement for glass protective covers, as the material has optical transparency. Other non-limiting examples of articles of manufacture include windows, eyewear (e.g, lenses, visors, sunglasses, goggles etc.), windshields, monitors, displays, surfaces of a building, traffic signs, skylights, surfaces of an automobile or a motorcycle, etc. Non-limiting examples of substrates include plastic substrates, glass substrates, wood substrates, paper substrates, ceramic substrates, metal substrates, or mixtures thereof. The material of the present invention can be formed into a film. The thickness of the film can be selected as desired for a given application. For instance, the thickness can range from 5 microns to 2 mm. The materials of the present invention can also be thermally or dimensionally stable when exposed to 60° C., 70° C., 80° C. 90° C., 100° C., or more for ten minutes (i.e., the material does not expand or shrink or otherwise deform such that the treated surface loses its ability to impart self-cleansing or antifouling properties to a given article of manufacture or substrate). The treated surface of the material of the present invention can have a roughness (Ra) of from about 100 nm to about 5 μm, or any range or integer therein. In certain aspects, the super-hydrophobic material or the polymeric layer or both do not include inorganic compounds or additives (e.g., metal) or do not include components that are not etchable via plasma-treatment with oxygen or do not include both inorganic materials and non-etchable components other than colloidal silica or silica.

Also disclosed is a method of making any one of the optically transparent super-hydrophobic materials of the present invention. The method can include: (a) obtaining an optically transparent polymeric layer having a first surface and an opposing second surface, wherein the first surface has a water contact angle of less than 150°; (b) subjecting at least a portion of the first surface of the polymeric layer to a first plasma comprising oxygen under reaction conditions sufficient to obtain nano- or micro-structures that are etched into the polymeric layer, wherein the nano- or micro-structures have a height to width aspect ratio of greater than 1; and (c) subjecting the treated surface from (b) to a second plasma comprising a fluorine containing compound under reaction conditions sufficient to chemically modify the nano- or micro-structures with the fluorine containing compound, wherein the treated surface from step (c) has a water contact angle of at least 150°, and wherein the optically transparent polymeric layer from (a) retains its optical transparency after steps (b) and (c). In certain aspects, steps (b) and (c) can be performed in a continuous process such that the oxygen from step (b) is switched to the fluorine containing compound from step (c) without stopping the process (e.g., continuous plasma treatment via switching plasma streams during operation). The types of polymers, fluorine-containing compounds, functional coatings, and other materials and components discussed about and throughout this specification can be used with the processes of the present invention. By way of example only, the polymer can be a polycarbonate or blend thereof, the functional coating can be a silicone hardcoat, the fluorine containing compound can be C₄F₈, etc. Notably, the plasma treatment processes of the present invention do not negatively affect the spectral or structural properties of the polymeric layer used to make the materials of the present invention. For instance, the optically transparent polymeric layer can retain its optical transparency after said plasma-treatment. If a functional coating is present pre-plasma treatment, the functional properties of the coating can also be retained (e.g. ultra-violet light absorption between 100 to below 400 nm is maintained and/or abrasion resistant properties can be retained, etc.). Therefore, and in one non-limiting aspect, it can be said that the polymeric layers used in the plasma treatment process of the present invention can maintain their spectral profile for transmission of visible light (400 nm-700 nm) and absorbance of ultra-violet light (100-400 nm). By maintaining or retaining the spectral profile, the difference between pre- and post-plasma treatment of the visible light transmission or of absorbance of ultra-violet light, or both, does not vary by more than 10%, or by more than 5%, or by more than 4, 3, 2, or 1%. The following non-limiting parameters can be used for the plasma processing conditions: Time for each plasma treatment step can range from 1 min. to 25 min.; Type of plasma for each treatment step can be generated by a glow discharge, corona discharge, Arc discharge, Townsend discharge, dielectric barrier discharge, hollow cathode discharge, radio-frequency (RF) discharge, microwave discharge, or electron beams-preferred power range can be 50 to 150 W or about 100 W when RF power is used; temperature used can be about 50° C. or a range of about 40 to 60° C.; pressure used can be 25 to 100 mTorr; and plasma gas flow rates can be 10 to 100 sccm.

In yet another aspect of the present invention, there is disclosed a method of protecting a substrate or article of manufacture from soiling, the method comprising disposing any one of the optically transparent super-hydrophobic materials of the present invention onto a substrate or article of manufacture, wherein the super-hydrophobic material protects the substrate or article of manufacture from soiling. In particularly preferred aspects, the article of manufacture can be a solar panel, and the material of the present invention can be used as the protective cover of the solar panel. As noted elsewhere however, all types of substrates and articles of manufacture can be used in the context of the present invention. In instances, where the material of the present invention is used as a protective cover for a solar panel, the efficiency of the panel can be maintained via the self-cleansing or antifouling properties of the material. For example, less dirt, build-up, materials, etc., will be present on the panel, thereby maximizing the light exposure of the active layer(s) of the solar panels.

Also contemplated in the context of the present invention is the use of non-fluorinated compounds that can impart the aforementioned super-hydrophobic properties to the treated surface. Non-limiting examples of such compounds include poly(glycidyl methacrylates), poly3-(trimethoxyethyl methacrylates) and sol-gel polymeric network based on hexadecyltrimethoxysilane precursors. Alternatively, the processes of the present invention can be used to create hydrophilic or super-hydrophilic surfaces by functionalizing the surfaces with hydrophilic compounds rather than hydrophobic compounds. Non-limiting examples of hydrophilic compounds include polyamides, polyimides, polyoxymethylenes and amino-epoxy resins and or combinations or blends thereof. The same processing steps and conditions discussed throughout this specification can be used with non-fluorinated hydrophobic compounds or hydrophilic compounds to achieve a desired surface property. Still further, the plasma processing steps of the present invention can be modified or tuned as desired to achieve a given property (e.g., particular water-contact angles, particular water rolling angles, and particular hysteresis angles) or surface morphology (e.g., nanopillars, nanospheres, micropillars, microspheres, etc.) or both. The modifications can be done by modifying plasma treatment times, power used, type of plasma used, temperatures used, functional compounds used to achieve hydrophobicity or hydrophilicity, etc. By way of example, a particular water contact angle, a particular water rolling angle, and/or a particular hysteresis angle can be achieved in the context of the present invention for a particular purpose by “tuning” or modifying the above variables. Similarly, the variability of the treatment parameters allows for all types of surfaces to be treated in the context of the present invention. Thus, specific water contact angles such as 150, 151, 152, 153, 154, 155, 156, 157, 158, 159, 160, 161, 162, 163, 164, 165, 166, 167, 168, 169, 170, 171, 172, 173, 174, 175, 176, 177, 178, or 179 can be obtained by the processes of the present invention. However, and if desired, lower water contact angles can be created by tuning or varying the processing conditions (e.g., 90° to less than 150°, or greater than 45° to less than 90°). Additionally, specific water rolling angles of 9°, 8°, 7°, 6°, 5°, 4°, 3°, 2°, or 1° or less can be achieved. Also, specific hysteresis angles of 9°, 8°, 7°, 6°, 5°, 4°, 3°, 2°, or 1° or less can be achieved. If desired, water rolling angles and hysteresis angles of greater than 10°, 11°, 12°, 13°, 14°, 15°, 20°, or greater can be obtained. Still further, the surface morphology of the optically transparent super-hydrophobic material can be modified or tuned as desired by selecting or varying any one of the following processing conditions: plasma treatment times, amount of power used, type of plasma used, temperature of the plasmas; and/or fluorine containing compound used. By way of example, the process conditions can be such that nanostructures are obtained at the exclusion of micro-structures, or micro-structures are obtained at the exclusion of nanostructures, or both nano- and microstructures are obtained, or the ratio of nanostructures to microstructures present on the material can be increased or decreased as desired. Non-limiting examples of nano- and microstructures include nanopillars, micropillars, nanospheres, microspheres, irregular shapes, etc.

Also disclosed in the context of the present invention are embodiments 1 to 51. Embodiment 1 is an optically transparent super-hydrophobic material that includes an optically transparent polymeric layer having a first surface and an opposing second surface, wherein at least a portion of the first surface has been plasma-treated with oxygen and a fluorine containing compound, wherein the treated surface includes: (i) nano- or micro-structures that are etched into the first surface and that are chemically modified with the fluorine containing compound, wherein the nano- or micro-structures have a height to width aspect ratio of greater than 1; and (ii) a water contact angle of at least 150°, wherein the optically transparent polymeric layer retains its optical transparency after said plasma-treatment. Embodiment 2 is the optically transparent material of embodiment 1, wherein the polymeric layer includes a polycarbonate or a blend thereof. Embodiment 3 is the optically transparent material of any one of embodiments 1 to 2, wherein the at least a portion of the first surface includes a functional coating, and wherein the functional coating retains its functional properties after said plasma-treatment. Embodiment 4 is the optically transparent material of embodiment 3, wherein the functional coating is a silicone hard-coat. Embodiment 5 is the optically transparent material of any one of embodiments 3 to 4, wherein the functional coating is capable of absorbing ultra-violet (UV) light, and wherein the functional coating retains its ability to absorb UV light after said plasma-treatment. Embodiment 6 is the optically transparent material of any one of embodiments 1 to 5, wherein the fluorine containing compound is an organofluorine. Embodiment 7 is the optically transparent material of embodiment 6, wherein the organofluorine is a fluorocarbon. Embodiment 8 is the optically transparent material of embodiment 7, wherein the fluorocarbon is CF₄, C₂F₄, C₂F₆, C₄F₆, C₄F₈, or any combination thereof. Embodiment 9 is the optically transparent material of embodiment 7, wherein the fluorocarbon is C₄F₈. Embodiment 10 is the optically transparent material of any one of embodiments 1 to 9, wherein the at least a portion of the first surface has been plasma treated with a first plasma comprising oxygen followed by a second plasma comprising the fluorine containing compound. Embodiment 11 is the optically transparent material of any one of embodiments 1 to 10, wherein the nano-structures have a width in the range between about 10 to 100 nm or wherein the spacing between two adjacent nano-structures is in the range between about 10 to 100 nm or both. Embodiment 12 is the optically transparent material of any one of embodiments 1 to 11, wherein the spacing between two adjacent nano-structures is greater than the width of a single nano-structure. Embodiment 13 is the optically transparent material of any one of embodiments 1 to 12, wherein the polymeric layer includes a polyethylene terephthalate, a polyolefin, a polystyrene, a poly(methyl)methacrylate, a polyacrylonitrile, a poly(vinylacetate), a poly(vinyl alcohol), a chlorine-containing polymer, a polyoxymethylene, a polyamide, a polyimide, a polyurethane, an amino-epoxy resin, or a polyester, or combinations or blends thereof. Embodiment 14 is the optically transparent material of any one of embodiments 1 to 13, wherein the material is disposed on a substrate or comprised in an article of manufacture. Embodiment 15 is the optically transparent material of any one of embodiments 1 to 13, wherein the material is disposed on an article of manufacture. Embodiment 16 is the optically transparent material of any one of embodiments 14 to 15, wherein the article of manufacture is a photovoltaic cell or a solar panel. Embodiment 17 is the optically transparent material of any one of embodiments 14 to 15, wherein the article of manufacture is a window, eyewear, a surface of a building, a traffic sign, a skylight, or a surface of an automobile or a motorcycle. Embodiment 18 is the optically transparent material of any one of embodiments 14 to 15, wherein the substrate is a plastic, a glass, a wood, a paper, a ceramic, a metal, or mixtures thereof. Embodiment 19 is the optically transparent material of any one of embodiments 1 to 18, wherein the material is in the form of a film. Embodiment 20 is the optically transparent material of any one of embodiments 1 to 19, wherein the treated surface has a water rolling angle of <10° or a hysteresis angle of <10° or both. Embodiment 21 is the optically transparent material of any one of embodiments 1 to 20, wherein the material is thermally stable when exposed to 60° C. for ten minutes. Embodiment 22 is the optically transparent material of any one of embodiments 1 to 21, wherein the material is dimensionally stable up to 80° C. Embodiment 23 is the optically transparent material of any one of embodiments 1 to 22, wherein covalent bonds are formed between the nano- or micro-structures and individual fluorine containing compounds. Embodiment 24 is the optically transparent material of any one of embodiments 1 to 23, wherein the polymeric layer does not include an inorganic compound. Embodiment 25 is the optically transparent material of any one of embodiments 1 to 24, wherein the at least a portion of the first surface that has been plasma-treated does not include a component that is not etchable via plasma-treatment with oxygen.

Embodiment 26 is a method of preparing any one of the optically transparent super-hydrophobic materials of embodiments 1 to 25. Such a method includes (a) obtaining an optically transparent polymeric layer having a first surface and an opposing second surface, wherein the first surface has a water contact angle of less than 150°; (b) subjecting at least a portion of the first surface of the polymeric layer to a first plasma comprising oxygen under reaction conditions sufficient to obtain nano- or micro-structures that are etched into the polymeric layer, wherein the nano- or micro-structures have a height to width aspect ratio of greater than 1, and (c) subjecting the treated surface from (b) to a second plasma comprising a fluorine containing compound under reaction conditions sufficient to chemically modify the nano- or micro-structures with the fluorine containing compound, wherein the treated surface from step (c) has a water contact angle of at least 150°, and wherein the optically transparent polymeric layer from (a) retains its optical transparency after steps (b) and (c). Embodiment 27 is the method of embodiment 26, wherein steps (b) and (c) are performed in a continuous process such that the oxygen from step (b) is switched to the fluorine containing compound from step (c) without stopping the process. Embodiment 28 is the method of any one of embodiments 26 to 27, wherein the polymeric layer comprises a polycarbonate or a blend thereof. Embodiment 29 is the method of any one of embodiments 26 to 28, wherein the at least a portion of the first surface in step (b) comprises a functional coating, and wherein the functional coating retains its abrasion resistant properties after steps (b) and (c). Embodiment 30 is the method of embodiment 29, wherein the functional coating is a silicone hard-coat. Embodiment 31 is the method of any one of embodiments 29 to 30, wherein the functional coating is capable of absorbing ultra-violet (UV) light, and wherein the functional coating retains its ability to absorb UV light after steps (b) and (c). Embodiment 32 is the method of any one of embodiments 26 to 31, wherein the fluorine containing compound is an organofluorine. Embodiment 33 is the method of embodiment 32, wherein the organofluorine is a fluorocarbon selected from the group consisting of CF₄, C₂F₄, C₂F₆, C₃F₆. C₄F₈, or any combination thereof. Embodiment 34 is the method of any one of embodiments 26 to 33, wherein steps (b) and (c) are dry plasma etching processes. Embodiment 35 is the method of any one of embodiments 26 to 34, wherein the plasma from step (b) comprises pure O2 and the plasma from step (c) comprises C₄F₈. Embodiment 36 is the method of any one of embodiments 26 to 35, wherein step (b) is performed for 1 minute to 25 minutes and wherein step (c) is performed for 1 minute to 25 minutes. Embodiment 37 is the method of any one of embodiments 26 to 36, wherein the plasma is generated by a glow discharge, corona discharge, Arc discharge. Townsend discharge, dielectric barrier discharge, hollow cathode discharge, radio-frequency (RF) discharge, microwave discharge, or electron beams. Embodiment 38 is the method of any one of embodiments 26 to 37, wherein the plasma is generated by a RF discharge having a RF power of 50 to 950 W or about 100 W. Embodiment 39 is the method of any one of embodiments 26 to 38, wherein the steps (b) and (c) are each performed at a temperature of 40° C. to 50° C. at a pressure of 10 to 100 mTorr, and plasma gas flow rates of about 90 to 100 sccm. Embodiment 40 is the method of any one of embodiments 26 to 39, wherein the polymeric layer comprises a polyethylene terephthalate, a polyolefin, a polystyrene, a poly(methyl)methacrylate, a polyacrylonitrile, a poly(vinylacetate), a poly(vinyl alcohol), a chlorine-containing polymer, a polyoxymethylene, a polyamide, polyimide, a polyurethane, an amino-epoxy resin, or a polyester, or combinations or blends thereof. Embodiment 41 is the method of any one of embodiments 26 to 40, wherein a target water contact angle is obtained by tuning or modifying any one of the following processing conditions: plasma treatment times, amount of power used, type of plasma used, temperature of the plasmas; and/or fluorine containing compound used. Embodiment 41 is the method of embodiment 41, wherein a target water rolling angle or a target hysteresis angle or both are obtained by tuning or modifying said processing conditions. Embodiment 42 is the method of any one of embodiments 26 to 42, wherein the nano- or micro-structure is obtained by tuning or modifying any one of the following processing conditions: plasma treatment times, amount of power used, type of plasma used, temperature of the plasmas; and/or fluorine containing compound used. Embodiment 44 is the method of embodiment 43, wherein the nano- or micro-structure is a nanopillar or a micropillar. Embodiment 45 is a method of protecting a substrate or article of manufacture from soiling, the method comprising disposing any one of the optically transparent super-hydrophobic materials of embodiments 1 to 25 onto a substrate or article of manufacture, wherein the super-hydrophobic material protects the substrate or article of manufacture from soiling. Embodiment 46 is the method of embodiment 45, wherein the article of manufacture is a photovoltaic cell or a solar panel. Embodiment 47 is the method of any one of embodiments 45 or 46, wherein the article of manufacture is a window, eyewear, a surface of a building, a traffic sign, a skylight, or a surface of an automobile or a motorcycle. Embodiment 48 is the method of any one of embodiments 45 to 47, wherein the substrate is a plastic, a glass, a wood, a paper, a ceramic, a metal, or mixtures thereof. Embodiment 49, is a method of maintaining or increasing the efficiency of a photovoltaic cell or protecting the outermost surface of a photovoltaic cell from soiling, the method comprising disposing any one of the optically transparent super-hydrophobic materials of embodiments 1 to 25 onto the outermost surface of the photovoltaic cell, wherein the efficiency of the photovoltaic cell is maintained or increased by protecting the outermost surface of the photovoltaic cell from soiling. Embodiment 50 is the method of embodiment 49, wherein the photovoltaic cell is a solar cell. Embodiment 51 is the method of embodiment 50, wherein the super-hydrophobic material is disposed onto the outer surface of a solar panel of the solar cell.

“Optically transparent” and “optically clear” polymeric materials and layers of the present invention refer to such materials or layers that have at least 70% or more light transmission in the visible spectrum (400 nm-700 nm). In more preferred aspects, the light transmission can be 75%, 80%, 85%, 90%, 95%, or more. Transmission, haze, and clarity values can be measured by using the reference standard American Society for Testing Materials (ASTM) D1003, which an internationally known and accepted standard for measuring such values.

The phrases “super-hydrophobic” or “super-hydrophobicity” refers to a surface of a material where water droplets have a contact angle (“water contact angle” or “WCA”) of at least 150°, as measured by the method used in the Examples section of this specification. “Hydrophobic” refers to materials or surfaces having a WCA of 90 to less than 150°.

The terms “polymer” refers to homopolymers, copolymers, blends of homopolymers, blends of copolymers, and blends of homopolymers and copolymers.

The terms “about” or “approximately” are defined as being close to as understood by one of ordinary skill in the art, and in one non-limiting embodiment the terms are defined to be within 10%, preferably within 5%, more preferably within 1%, and most preferably within 0.5%.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The super-hydrophobic materials of the present invention, and related processes of making and using said materials, can “comprise,” “consist essentially of,” or “consist of” particular ingredients, components, compounds, compositions, processing steps etc. disclosed throughout the specification. With respect to the transitional phase “consisting essentially of,” in one non-limiting aspect, a basic and novel characteristic of the aforesaid materials is their super-hydrophobic or self-cleaning characteristics.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIG. 1: Illustration of a super-hydrophobic material of the present invention being used as a protective cover for a solar panel.

FIGS. 2A-D: An illustration of the self-cleaning ability illustration of the plasma treated silicone hard-coated polycarbonate (SHC-PC) of the present invention.

FIG. 3: SEM image of SHC-PC prior to plasma treated (insert: water contact angle (WCA) 820).

FIG. 4: SEM image of O₂ plasma treated SHC-PC (insert: water contact angle (WCA)<10°).

FIG. 5: SEM image of O₂/C₄F₈ plasma treated SHC-PC (insert: water contact angle (WCA) 1680).

FIG. 6: Transmission UV-Vis profiles of pre-treated and post-treated of O₂/C₄F_{K} plasma treated SHC-PC of the present invention.

FIG. 7A: 3D AFM images of O₂ plasma treated SHC-PC of the present invention.

FIG. 7B: 3D AFM images of O₂ plasma O₂/C₄F₈ plasma treated SHC-PC of the present invention showing needle like structures of variable mean surface roughness.

FIG. 8A: Optical profilometry images of O₂ plasma treated SHC-PC of the present invention

FIG. 8B: Optical profilometry images of O₂/C₄F₈ plasma treated SHC-PC of the present invention showing different surface topology and roughness.

FIG. 9: Graphical representation of variation of water contact angle of O2/C₄F₈ plasma treated SHC-PC of the present invention versus treatment time.

FIG. 10: An image of the plasma treated SHC-PC after 10 min of DRIE plasma processing showing the optical clarity of the SHC-PC.

FIG. 11A: An image of the plasma treated SHC-PC after immersion in organic solvents.

FIG. 11B: An image of a comparative sample of polycarbonate after immersion in acetone.

FIG. 12A: An image of DRIE plasma treated SHC-PC of the present invention at 60° C. (on hot heating plate surface) showing no conformal shrinkage or expansion of the SHC-PC.

FIG. 12B: An image of DRIE plasma treated comparative sample of polycarbonate at 60° C. showing structural deformation.

FIG. 13A: An image of water beads on plasma treated SHC-PC material of the present invention.

FIG. 13B: An image of water beads on comparative sample of an untreated SHC-PC material.

FIG. 14A: An image of self-cleaning of dust from the surface of a plasma treated SHC-PC material of the present invention.

FIG. 14B: An image of self-cleaning of dust from the surface of a comparative sample of an untreated SHC-PC material.

### DETAILED DESCRIPTION OF THE INVENTION

The present invention relates generally to plasma treatment processes that can create polymeric materials having sufficient durability, optical transparency, and self-cleansing properties. The plasma processes can be performed without the use of solvents (e.g., deep reactive ion etching), thereby reducing the risk of cross-contamination with the polymeric material that is to be treated. Materials produced by the processes of the present invention can have a polymeric layer having nano- or micro-structures and a water contact angle of at least 150°. As illustrated in a non-limiting aspect in the Examples, the materials of the present invention can exhibit any one of or all of the following properties post-plasma treatment:
1. Maintain high transmission (e.g., at least 70%) in the visible spectrum.
2. Maintain low transmission in the ultra-violet light spectrum (e.g., less than 2% at 330 nm.
3. Have a water contact angle of at least 150°, a low hysteresis angle (e.g., <10°), and a low water rolling angle (e.g., <10°).
4. Have chemical resistance to a variety of solvents and cleansing materials (e.g., alcohols (e.g., methanol and ethanol), ketones, DMF, chlorinated solvents (e.g., chlorobenzene and toluene), etc.).
5. Have sufficient thermal stability characteristics (e.g., no evidence of softening when exposed to 60° C. for ten minutes).
6. Retain conformal dimensional stability with no evidence of size reduction or expansion at 80° C.
7. Provide self-cleansing polymeric material that can be integrated into a variety of products (e.g., solar panels).
8. Provide opportunities to develop water-repelling transparent coatings for various applications relating to the automotive industry, anti-fogging products, and anti-fouling products.

These and other non-limiting aspects of the present invention are discussed in detail in the following sections.

### A. Polymeric Materials Having Optical Transparency and Sufficient Impact Strength

Polymers and matrices having optical clarity and sufficient impact strength include those that can be used to form films and layers in products that require such features—e.g., photovoltaic cells or solar panels, automotive headlamp lenses, lighting lenses, sunglass lenses, eyeglass lenses, swimming goggles and SCUBA masks, safety glasses/goggles/visors including visors in sporting helmets/masks, windscreens in motorized vehicles (e.g., motorcycles, ATVs, golf carts), electronic display screens (e.g., e-ink, LCD, CRT, plasma screens), etc. Non-limiting examples of polymers that can be used to form the materials and layers of the present invention include polycarbonate polymers or copolymers thereof, polyethylene terephthalates or co-polymers thereof, polysulphone polymers or co-polymers thereof, cyclo olefin polymers or co-polymers thereof, thermoplastic polyurethane polymers or co-polymers thereof, thermoplastic polyolefin polymers or co-polymers thereof, polystyrene polymers or co-polymers thereof, poly(methyl)methacrylate polymers or co-polymers thereof, and any other optically transparent polymers or co-polymers thereof. Blends of the aforementioned polymers and co-polymers can also be used.

In a preferred embodiment of the present invention, polycarbonates (PCs) are used. PCs include a particular class of thermoplastic polymers that are commercially available from a wide variety of sources (e.g., Sabic Innovative Plastics (Lexan®)). In a particularly preferred embodiment, Lexan® can be used in the context of the present invention. PCs typically have high impact-resistance and are highly transparent to visible light, with light transmission properties that exceed many types of glass products. Preferred examples of PCs include dimethyl cyclohexyl bisphenol or high-flow ductile (HFD) polycarbonates (e.g., bisphenol-A polycarbonate, sebacic acid copolymer).

PCs are polymers that include repeating carbonate groups (—O—(C═O)—O—). A well-known PC is bisphenol-A polymer, which has the following structure:

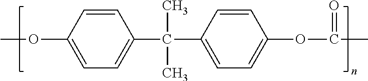

However, all types of polycarbonates, co-polymers, and blends thereof are contemplated in the context of the present invention. By way of example, and in addition to the dimethyl cyclohexyl bisphenol and high-flow ductile (HFD) polycarbonates (e.g., bisphenol-A polycarbonate, sebacic acid copolymer) mentioned above, WO 2013/152292 (the contents of which are incorporated into the present specification by reference) provides a wide range of PCs that can be used. In particular, “polycarbonates” can include polymers having repeating structural carbonate units of formula (1):

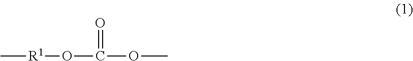

in which at least 60°/o of the total number of R¹ groups contain aromatic moieties and the balance thereof are aliphatic, alicyclic, or aromatic. In an embodiment, each R¹ is a C₆₋₃₀ aromatic group, that contains at least one aromatic moiety. R¹ can be derived from a dihydroxy compound of the formula HO—R²OH, in particular of formula (2):

OH-A¹-Y¹-A²OH (2)

in which each of A¹ and A² is a monocyclic divalent aromatic group and Y 1 is a single bond or a bridging group having one or more atoms that separate A 1 from A 2. In an embodiment, one atom separates A¹ and A². Specifically, each R¹ can be derived from a dihydroxy aromatic compound of formula (3):

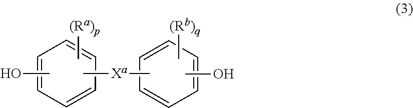

wherein R^{a} and R^{b} are each independently a halogen or C₁₋₁₂ alkyl group; and p and q are each independently integers of 0 to 4. It will be understood that R is hydrogen when p is 0, and likewise R^{b} is hydrogen when q is 0. Also in formula (3), X^{a} is a bridging group connecting the two hydroxy-substituted aromatic groups, where the bridging group and the hydroxy substituent of each C₆ arylene group are disposed ortho, meta, or para (specifically para) to each other on the C₆ arylene group. In an embodiment, the bridging group X^{a} is single bond, —O—, —S—, —S(O)—, —S(O)₂—, —C(O)—, or a C₁₋₁₈ organic group. The C₁₋₁₈ organic bridging group can be cyclic or acyclic, aromatic or non-aromatic, and can further comprise heteroatoms such as halogens, oxygen, nitrogen, sulfur, silicon, or phosphorous. The C₁₋₁₈ organic group can be disposed such that the C₆ arylene groups connected thereto are each connected to a common alkylidene carbon or to different carbons of the C₁₋₁₈ organic bridging group. In an embodiment, p and q is each 1, and R^{a} and R^{b} are each a C₁₋₃ alkyl group, specifically methyl, disposed meta to the hydroxy group on each arylene group.

In an embodiment, X^{a} can be a substituted or unsubstituted C₁₋₈ cycloalkylidene, a C₁₋₂₅ alkylidene of formula —C(R^{c})(R^{d})—wherein R^{c} and R^{d} are each independently hydrogen, C₁₋₁₂ alkyl, C₁₋₁₂ cycloalkyl. C₇₋₁₂ arylalkyl, C₁₋₁₂ heteroalkyl, or cyclic C₇₋₁₂ heteroarylalkyl, or a group of the formula —C(═R^{e})—wherein R^{e} is a divalent C₁₋₁₂ hydrocarbon group. Groups of this type include methylene, cyclohexylmethylene, ethylidene, neopentylidene, and isopropylidene, as well as 2-[2.2.1]-bicycloheptylidene, cyclohexylidene, cyclopentylidene, cyclododecylidene, and adamantylidene. A specific example wherein X^{a} is a substituted cycloalkylidene is the cyclohexylidene-bridged, alkyl-substituted bisphenol of formula (4)

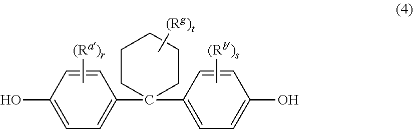

wherein R^{a} and R^{b}, are each independently C₁₋₁₂ alkyl, R is C₁₋₁₂ alkyl or halogen, r and s are each independently 1 to 4, and t is 0 to 10. In a specific embodiment, at least one of each of R^{a} and R^{b} are disposed meta to the cyclohexylidene bridging group. The substituents R^{a′}, R^{b′}, and R^{g} can, when comprising an appropriate number of carbon atoms, be straight chain, cyclic, bicyclic, branched, saturated, or unsaturated. In an embodiment, R^{a′} and R^{b′} are each independently C₁₋₄ alkyl, R^{g} is C₁₋₄ alkyl, r and s are each 1, and t is 0 to 5. In another specific embodiment, R^{a′}, R^{b′} and R^{g} are each methyl, r and s are each 1, and t is 0 or 3. The cyclohexylidene-bridged bisphenol can be the reaction product of two moles (mol) of o-cresol with one mole of cyclohexanone. In another embodiment, the cyclohexylidene-bridged bisphenol is the reaction product of two moles of a cresol with one mole of a hydrogenated isophorone (e.g., 1,1,3-trimethyl-3-cyclohexane-5-one). Such cyclohexane-containing bisphenols, for example the reaction product of two moles of a phenol with one mole of a hydrogenated isophorone, are useful for making polycarbonate polymers with high glass transition temperatures and high heat distortion temperatures.

In another embodiment, X^{a} can be a C₁₋₈ alkylene group, a C₃₋₈ cycloalkylene group, a fused C₆₋₁₈ cycloalkylene group, or a group of the formula —B¹—W—B²—wherein B¹ and B² are the same or different C₁₋₆ alkylene group and W is a C₃₋₁₂ cycloalkylidene group or a C₆₋₁₆ arylene group.

X^{a} can also be a substituted C₃₋₁₈ cycloalkylidene of formula (5)

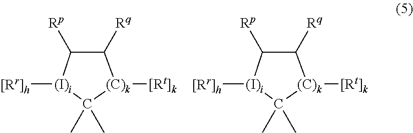

wherein R^{r}, R^{p}, R^{q}, and R^{t} are each independently hydrogen, halogen, oxygen, or C₁₋₁₂ organic groups; I is a direct bond, a carbon, or a divalent oxygen, sulfur, or —N(Z)— where Z is hydrogen, halogen, hydroxy, C₁₋₁₂ alkyl, C₁₋₁₂ alkoxy, or C₁₋₁₂ acyl; h is 0 to 2, j is 1 or 2, i is an integer of 0 or 1, and k is an integer of 0 to 3, with the proviso that at least two of R^{r}, R^{p}, R^{q}, and R^{t} taken together are a fused cycloaliphatic, aromatic, or heteroaromatic ring. It will be understood that where the fused ring is aromatic, the ring as shown in formula (5) will have an unsaturated carbon-carbon linkage where the ring is fused. When k is one and i is 0, the ring as shown in formula (5) contains 4 carbon atoms, when k is 2, the ring as shown in formula (5) contains 5 carbon atoms, and when k is 3, the ring contains 6 carbon atoms. In an embodiment, two adjacent groups (e.g., R^{q} and R^{t} taken together) form an aromatic group, and in another embodiment, R^{q} and R^{t} taken together form one aromatic group and R^{r} and R^{p} taken together form a second aromatic group. When R^{q} and R^{t} taken together form an aromatic group, R^{p} can be a double-bonded oxygen atom, i.e., a ketone.

Other useful aromatic dihydroxy compounds of the formula HO-R̂OH include compounds of formula (6)

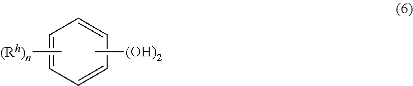

wherein each R^{b} is independently a halogen atom, a C₁₋₁₀ hydrocarbyl such as a C₁₋₁₀ alkyl group, a halogen-substituted C₁₋₁₀ alkyl group, a C₆₋₁₀ aryl group, or a halogen-substituted C₆₋₁₀ aryl group, and n is 0 to 4. A preferred halogen is bromine.

Some illustrative examples of specific aromatic dihydroxy compounds include the following: 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis(hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene, 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl) sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9, 10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5, 6-tetrabromo hydroquinone, or the like, or combinations comprising at least one of the foregoing dihydroxy compounds.

Specific examples of bisphenol compounds of formula (3) include 1,1-bis(4-hydroxyphenyl) methane, 1,1-bis(4-hydroxyphenyl) ethane, 2,2-bis(4-hydroxyphenyl) propane (hereinafter “bisphenol A” or “BPA”), 2,2-bis(4-hydroxyphenyl) butane, 2,2-bis(4-hydroxyphenyl) octane, 1,1-bis(4-hydroxyphenyl) propane, 1,1-bis(4-hydroxyphenyl) n-butane, 2,2-bis(4-hydroxy-2-methylphenyl) propane, 1,1-bis(4-hydroxy-t-butylphenyl) propane, 3,3-bis(4-hydroxyphenyl) phthalimidine, 2-phenyl-3,3-bis(4-hydroxyphenyl) phthalimidine (PPPBP), and 1,1-bis(4-hydroxy-3-methylphenyl)cyclohexane (DMBPC). Combinations comprising at least one of the foregoing dihydroxy compounds can also be used. In one specific embodiment, the polycarbonate is a linear homopolymer derived from bisphenol A, in which each of A¹ and A² is p-phenylene and Y¹ is isopropylidene in formula (3).

Methods for the preparation of polycarbonates by interfacial polymerization are well known. Although the reaction conditions of the preparative processes may vary, several of the useful processes typically involve dissolving or dispersing the dihydric phenol reactant in aqueous caustic soda or potash, adding the resulting mixture with the siloxane to a suitable water immiscible solvent medium and contacting the reactants with the carbonate precursor, such as phosgene, in the presence of a suitable catalyst such as triethylamine or a phase transfer catalyst, and under controlled pH conditions, e.g., 8 to 10. The most commonly used water immiscible solvents include, but are not limited to, methylene chloride, 1,2-dichloroethane, chlorobenzene, toluene, and the like.

Among the useful phase transfer catalysts that can be used are catalysts of the formula (R³)₄Q⁺X, wherein each R³ is the same or different, and is a C₁₋₁₀alkyl group; Q is a nitrogen or phosphorus atom; and X is a halogen atom or a C₁₋₈ alkoxy group or C₆₋₁₈₈ aryloxy group. Suitable phase transfer catalysts include, for example, [CH₃(CH₂)₃]₄NX, [CH₃(CH₂)₃]₄PX, [CH₃(CH₂)₅]₄NX, [CH₃(CH₂)₆]₄NX, [CH₃(CH₂)₃]₄NX, CH₃[CH₃(CH₂)₃]₃NX, CH₃[CH₃(CH₂)₂]₃NX wherein X is Cl⁻, Br⁻ or—a C₁₋₈ alkoxy group or C₆₋₁₈₈ aryloxy group. An effective amount of a phase transfer catalyst may be from 0.1 to 10 wt. %, and, in another embodiment, from 0.5 to 2 wt. % based on the weight of bisphenol in the phosgenation mixture.

In alternative embodiments, melt processes are used. A catalyst may be used to accelerate the rate of polymerization of the dihydroxy reactant(s) with the carbonate precursor. Representative catalysts include, but are not limited to, tertiary amines such as triethylamine, quaternary phosphonium compounds, quaternary ammonium compounds, and the like.

Alternatively, polycarbonates may be prepared by co-reacting, in a molten state, the dihydroxy reactant(s) and a diaryl carbonate ester, such as diphenyl carbonate, in the presence of a transesterification catalyst in a Banbury™ mixer, twin screw extruder, or other melt extrusion process equipment to form a uniform dispersion. Volatile monohydric phenol is removed from the molten reactants by distillation and the polymer is isolated as a molten residue.

The polycarbonates can be made in a wide variety of batch, semi-batch or continuous reactors. Such reactors are, for example, stirred tank, agitated column, tube, and recirculating loop reactors. Recovery of the polycarbonate can be achieved by any means known in the art such as through the use of an anti-solvent, steam precipitation or a combination of anti-solvent and steam precipitation.

“Polycarbonates” include homopolycarbonates (wherein each R¹ in the polymer is the same), copolymers comprising different R¹ moieties in the carbonate (“copolycarbonates”), copolymers comprising carbonate units and other types of polymer units, such as ester units, and combinations comprising at least one of homopolycarbonates and/or copolycarbonates.

### B. Functional Coatings

While many polymers that can be used in the context of the present invention have good optical transparency and impact resistance characteristics, many of such polymers lack good abrasion resistance and are also susceptible to degradation from exposure to ultra-violet light. In instances where it is desirable to increase the abrasion resistance and/or reduce exposure to ultra-violet light, of a given polymeric layer or material of the present invention, functional coatings can be applied to the polymeric layer prior to the plasma treatment steps.

The functional coating can be a weathering or protective coating. It can include silicones (e.g., a silicone hard-coat), polyurethanes (e.g., polyurethane acrylate), acrylics, polyacrylate (e.g., polymethacrylate, polymethyl methacrylate), polyvinylidene fluoride, polyesters, epoxies, and combinations comprising at least one of the foregoing. The functional coating can include ultraviolet absorbing molecules (e.g., such as hydroxyphenylthazine, hydroxybenzophenones, hydroxylphenylbenzothazoles, hydroxyphenyltriazines, polyaroylresorcinols, and cyanoacrylate, as well as combinations comprising at least one of the foregoing). In one preferred aspect of the present invention, the functional coatings are silicone hard-coats comprising condensed silanols, colloidal silica, and ultraviolet (UV) absorbers. Examples include AS4000, AS4010, and AS4700, all of which are available commercially from Momentive Performance Materials. Such coatings can be applied by dipping the plastic substrate layer in a coating solution at room temperature and atmospheric pressure (i.e., dip coating). Alternative methods such as flow coating, curtain coating, and spray coating can also be used.

The functional coating can comprise a primer layer and/or a coating (e.g., a top coat). A primer layer can aid in adhesion of the functional coating to the polymeric layer. The primer layer can include, but is not limited to, acrylics, polyesters, epoxies, and combinations comprising at least one of the foregoing. The primer layer can also include ultraviolet absorbers in addition to or in place of those in the functional coating. For example, the primer layer can comprise an acrylic primer (SHP401 or SHP470, commercially available from Momentive Performance Materials).

Another non-limiting example of a functional coating that can be used is an abrasion resistant coating to improve abrasion resistance. Generally, the abrasion resistant coating can comprise an organic coating and/or an inorganic coating such as, but not limited to, aluminum oxide, barium fluoride, boron nitride, hafnium oxide, lanthanum fluoride, magnesium fluoride, magnesium oxide, scandium oxide, silicon monoxide, silicon dioxide, silicon nitride, silicon oxy-nitride, silicon carbide, silicon oxy carbide, hydrogenated silicon oxy-carbide, tantalum oxide, titanium oxide, tin oxide, indium tin oxide, yttrium oxide, zinc oxide, zinc selenide, zinc sulfide, zirconium oxide, zirconium titanate, glass, and combinations comprising at least one of the foregoing. Such abrasion resistant coatings can be applied by various deposition techniques such as vacuum assisted deposition processes and atmospheric coating processes.

### C. Plasma Processing and Surface Treatment

Polymeric layers, whether coated with a functional coating or not, can be used in the context of the present invention. The surfaces of such layers can be treated with plasma techniques to impart super-hydrophobic self-cleansing properties to said surfaces. While both wet and drying etching plasma treatment techniques can be used, in preferred aspects dry etching is used. An advantage of dry etching is that solvents do not have to be used, and cross contamination of the solvents with the polymeric layers can be avoided.

Various dry etching techniques can be used in the context of the present invention, non-limiting examples of which include reactive ion etching (RIE), deep reactive ion etching (DRIE), ion beam etching (IBE), etc. In preferred aspects, the DRIE process is used. An objective is to reach a high ionization rate in the gases to enhance the RIE effect. Notably, the plasma treatment process can be a continuous process in which the polymeric layer is first subjected to plasma generated via oxygen to create a surface having the nano- and micro-structures. Subsequently, the oxygen plasma is replaced with fluorine containing compounds (e.g., C₄F₈) to functionalize the nano- or micro-structures, thereby imparting super-hydrophobic properties to the treated surface. In a preferred non-limiting embodiment, the following processing steps can be used in the context of the present invention:
1. A polymeric layer can be placed into an appropriate plasma chamber device such that one of its surfaces is faced towards the plasma flow (first surface) and the opposite surface is faced away from the plasma flow (second surface).
2. Pure oxygen gas can be introduced into the chamber at a flow rate of about 50 to 100 sccm at a base pressure of about 25 to 500 mTorr or 25 to 100 mTorr.
3. Plasma can be created via a radio frequency (RF) power source at about 50 to 950 W.
4. The first surface of the polymeric layer can be subjected to the O₂ generated plasma for about 1 minute to 25 minutes to create nano- and micro-structures.
5. Without shutting down the power source, the O₂ feed can be replaced with C₄F₈ at a similar flow rate to O₂ and under similar pressure and power conditions. The first surface of the polymeric layer can then be subjected to the C₄F₈ generated plasma for 1 minute to 25 minutes to functionalize the nano- and micro-structures, thereby imparting super-hydrophobicity to the treated surface.

Additives can also be included in the polymeric layer prior to plasma-treatment. The amounts of such additives can range from 0.001 to 40 wt. %. Non-limiting examples of such additives include plasticizers, ultraviolet absorbing compounds, optical brighteners, ultraviolet stabilizing agents, heat stabilizers, diffusers, mold releasing agents, antioxidants, antifogging agents, clarifiers, nucleating agents, phosphites or phosphonites or both, light stabilizers, singlet oxygen quenchers, processing aids, antistatic agents, fillers or reinforcing materials, or any combination thereof. Non-limiting examples of ultraviolet light absorbing compounds include those capable of absorbing ultraviolet A light comprising a wavelength of 315 to 400 nm (e.g., avobenzone (Parsol 1789), Bisdisulizole disodium (Neo Heliopan AP), Diethylamino hydroxybenzoyl hexyl benzoate (Uvinul A Plus), Ecamsule (Mexoryl SX), or Methyl anthranilate, or any combination thereof. Non-limiting examples of ultraviolet light absorbing compounds capable of absorbing ultraviolet B light comprising a wavelength of 280 to 315 nm include 4-Aminobenzoic acid (PABA), Cinoxate, Ethylhexyl triazone (Uvinul T 150). Homosalate, 4-Methylbenzylidene camphor (Parsol 5000), Octyl methoxycinnamate (Octinoxate), Octyl salicylate (Octisalate), Padimate O (Escalol 507), Phenylbenzimidazole sulfonic acid (Ensulizole). Polysilicone-15 (Parsol SLX), Trolamine salicylate. Non-limiting examples of ultraviolet light absorbing compounds capable of absorbing ultraviolet A and B light comprising a wavelength of 280 to 400 nm include Bemotrizinol (Tinosorb S), Benzophenones 1 through 12, Dioxybenzone, Drometrizole trisiloxane (Mexoryl XL). Iscotrizinol (Uvasorb HEB), Octocrylene, Oxybenzone (Eusolex 4360), Sulisobenzone, or polybenzoylresorcinol. Such additives can be compounded into a masterbatch with the desired polymeric resin.

### D. Applications for the Super-Hydrophobic Material

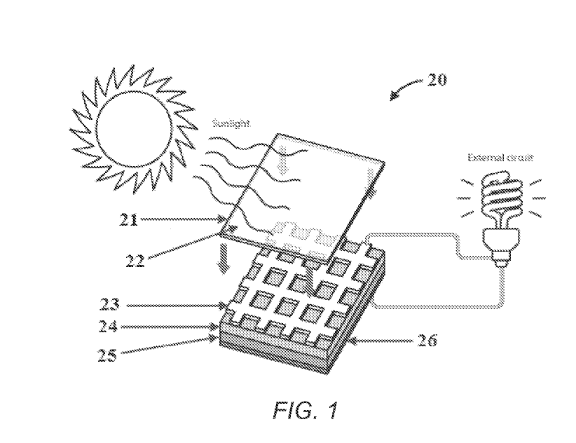

The super-hydrophobic materials of the present invention can be used in a wide variety of applications. For instance, and as illustrated in the Examples, the materials have sufficient optical and self-cleansing properties, strength, and structural integrity at elevated temperatures. Thus, the materials can be used to protect surfaces from soiling while also allowing visible light to pass-through. FIG. 1 provides a non-limiting example of the super-hydrophobic material of the present invention incorporated into a solar panel (20). The Solar panel (20) includes a super-hydrophobic material of the present invention (21) that includes a plasma treated surface having nano- or micro-structures and a water contact angle of at least °150 (22). The plasma treated surface (22) faces away from the solar panel (20), towards the sun, so as to provide its antifouling or self-cleansing effect while also protecting the internal parts of the solar panel (20). The internal parts can include a first electrode (23), a first active layer (24), a second active layer (25), and a second electrode (26).

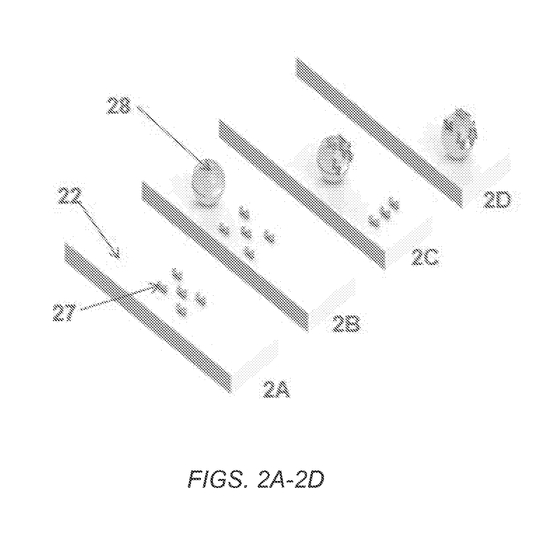

FIG. 2 provides a non-limiting illustration of the mechanism of the self-cleaning ability of the super-hydrophobic of the material of the present invention. In FIG. 2A, the plasma treated surface (22) has dirt particles (27) on the surface. Water is applied to the surface in FIG. 2B and the water forms droplet (28) due to the hydrophobic nature of the plasma treated surface. The dust particles (27) are attached to the droplet (28) as shown in FIGS. 2C and 2D.

Additional non-limiting examples of uses for the materials of the present invention include optical elements, displays, windows (or transparencies), mirrors, and liquid crystal cells. As used herein the term “optical” means pertaining to or associated with light and/or vision. The optical elements according to the present invention may include, without limitation, ophthalmic elements, display elements, windows, mirrors, and liquid crystal cell elements. As used herein the term “ophthalmic” means pertaining to or associated with the eye and vision. Non-limiting examples of ophthalmic elements include corrective and non-corrective lenses, including single vision or multi-vision lenses, which may be either segmented or non-segmented multi-vision lenses (such as, but not limited to, bifocal lenses, trifocal lenses and progressive lenses), as well as other elements used to correct, protect, or enhance (cosmetically or otherwise) vision, including without limitation, magnifying lenses, protective lenses, visors, goggles, as well as, lenses for optical instruments (for example, cameras and telescopes). As used herein the term “display” means the visible or machine-readable representation of information in words, numbers, symbols, designs or drawings. Non-limiting examples of display elements include screens, monitors, and security elements, such as security marks. As used herein the term “window” means an aperture adapted to permit the transmission of radiation there-through. Non-limiting examples of windows include automotive and aircraft transparencies, windshields, filters, shutters, and optical switches. As used herein the term “mirror” means a surface that specularly reflects a large fraction of incident light. As used herein the term “liquid crystal cell” refers to a structure containing a liquid crystal material that is capable of being ordered. One non-limiting example of a liquid crystal cell element is a liquid crystal display.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

### Super-Hydrophobic Material

Silicone hard-coated polycarbonate (SHC-PC) substrates were prepared from a silicone hard-coat obtained from Momentive Performance Materials, Inc. (AS4010) and a polycarbonate resin obtained from SABIC Innovative Plastics (LEXAN™). In particular, these substrates were prepared by injection molding a PC panel, flow-coating and curing the primer coating and flow-coating and curing the topcoat.

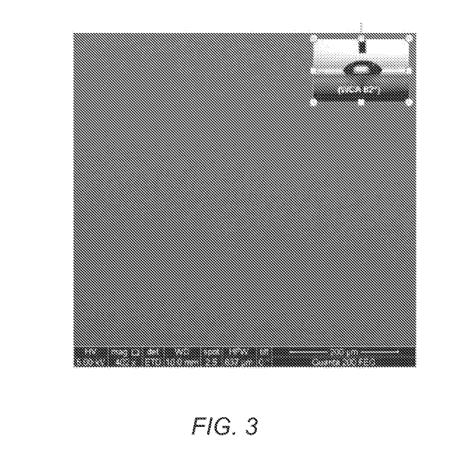

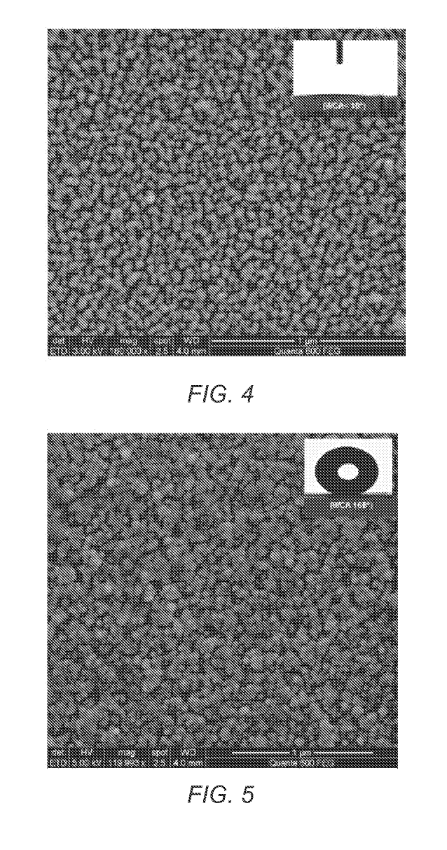

1×1 cm² samples were cleaned with isopropanol (IPA) and water, and then oven-dried at 50° C. for 15 minutes (See, FIG. 3). The polymer surfaces were then treated with plasma. The plasma treatment included etching and chemically modifying the samples using a deep reactive ion etching (DRIE) in a two-step continuous plasma process (pure oxygen for texturing and C₄F₈ for hydrophobization), which resulted in functional material that combine fluorinated chemistry with surface morphology. Surfaces were subjected to the O₂ and C₄F treatments for about 1 to 25 minutes to create the desired nano- and micro-structures. Gases were introduced into the chamber at a flow rate of 100 sccm, and the base pressure was kept at 85 mTorr while the RF power was maintained at 100 W in each experiment (See, FIGS. 4 and 5).

Surface morphologies were investigated by field emission scanning electron microscopy (SEM) using Quanta (200 or 600). The samples were gold-palladium metallized by sputter coating using a BioRad Polaron instrument and observed at 5-10 KV. Water contact angles were measured using a contact angle goniometer (KRUSS, Drop Shape Analyzer-DSA100 by KRUSS GmbH, Hamburg, Germany) at five different points of the samples using 10 μL of deionized water. Mean water contact angles were 820 pre-plasma treatment (FIG. 3), approximately 10° or less for oxygen plasma treated samples (FIG. 4) and 168° post-plasma for oxygen/C₄F₈ treatment (FIG. 5).

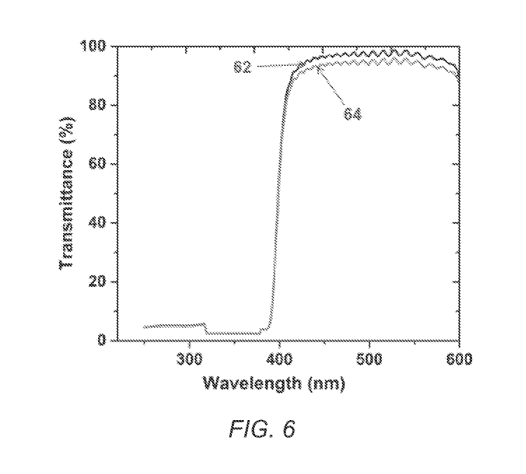

FIG. 6 are UV-Vis spectra data of SHC-PC before (data line 62) and 10 minutes after (data line 64) DRIE plasma treatment. These data confirm that the DRIE plasma processing does not negatively affect the ultra-violet (UV) absorbing properties of the SHC-PC substrate, as the UV spectrum is substantially the same. Thus, the UV spectral profile is maintained after DRIE plasma processing.

Fourteen samples of plasma-treated SHC-PC, along with a non-plasma-treated SHC-PC control sample, were exposed to UV light in an Atlas Ci5000 Xenon Arc Weatherometer according to ASTM G 155-05 Cycle 1 except with an irradiance of 0.75 W/m²·nm instead 0.35 W/m²·nm, both at 340 nm. After 6.7 MJ/m²·nm of exposure, equivalent to approximately 2.4 years of outdoor exposure in Florida, the plasma-treated samples and the control sample exhibited no delamination or micro-cracking. The change in haze, determined in accordance with ASTM D1003-11, procedure A with CIE standard illuminant C (see ISO/CIE 10526), was 2.0% for the control sample, was in the range 1.2 to 2.2% for the fourteen plasma-treated samples.

FIGS. 7A and B are 3D AFM images of O₂ plasma treated SHC-PC (FIG. 7A) and O₂/C₄F₈ plasma treated SHC-PC (FIG. 7B) showing needle like structures of variable mean surface roughness. Surface morphology examination was carried out using Agilent 5400 SPM Atomic Force Microscopy (AFM) scanner in non-contact mode. The reported root mean square surface roughness is the mean of three measurements on different areas of each sample taken to verify the surface sample homogeneity.

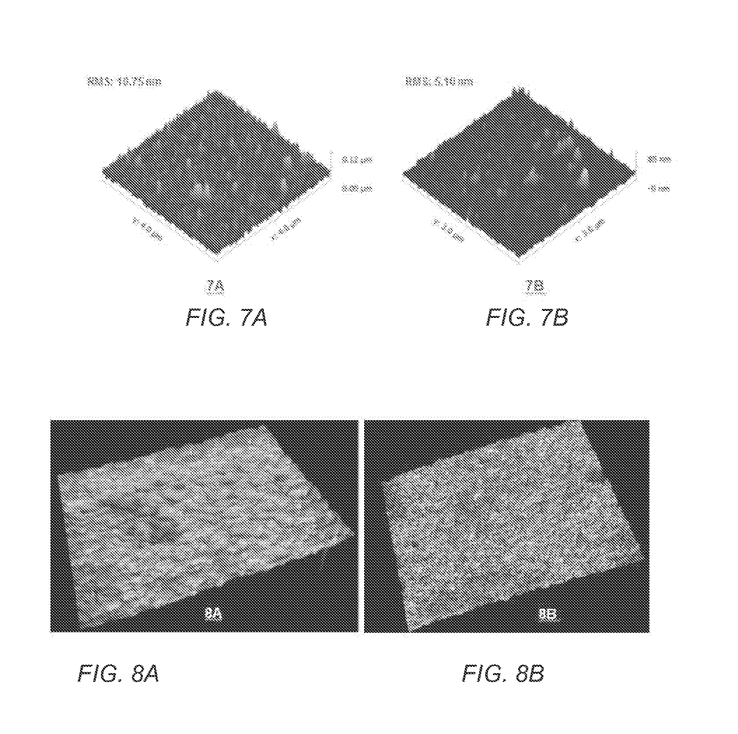

FIGS. 8A and 8B are optical surface profilometry images of O₂ plasma treated SHC-PC (FIG. 8A) and O₂/C₄F₈ plasma treated SHC-PC (FIG. 8B) showing different surface topology and roughness. Sample Surface roughness was mapped using ZYGO NewView 7300 optical profilometer scanning at 3 different sample spots (50×50 microns) in vertical scanning interferometer (VSI).

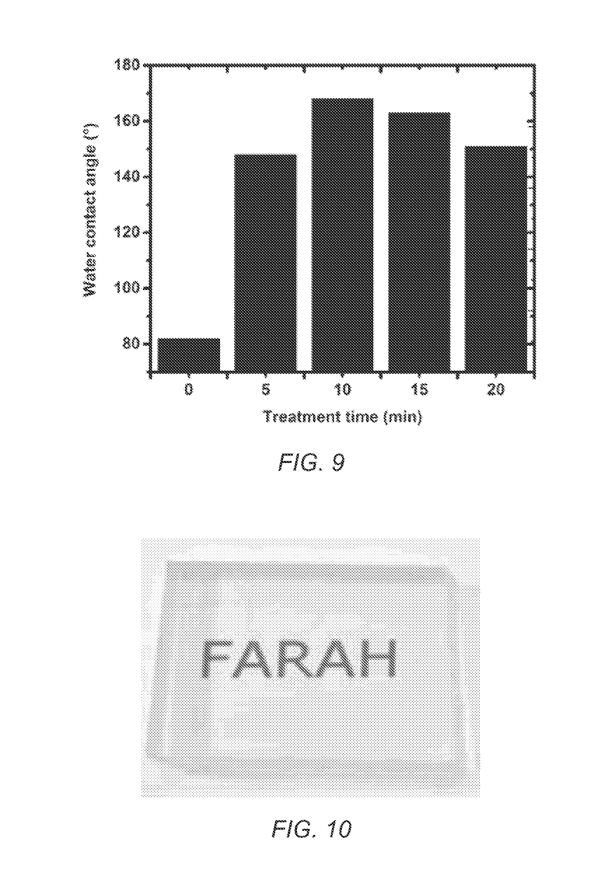

FIG. 9 is a bar graph of variation of water contact angle of O₂/C₄F₈ plasma treated SHC-PC material with different treatment time in minutes. This data confirmed the tunability of super-hydrophilicity/super-hydrophobicity nature of sequentially plasma treated samples with low hysteresis angle (100) and sliding angles less than (100), vital for their potential application in anti-soiling.

FIG. 10 is an image of a SHC-PC material demonstrating that the optical transparency of the SHC-PC is maintained after 10 minutes of DRIE plasma processing. Thus, the optical clarity is maintained after DRIE plasma processing. A before image is not provided, as no noticeable change was observed between before DRIE plasma processing and after DRIE plasma processing.

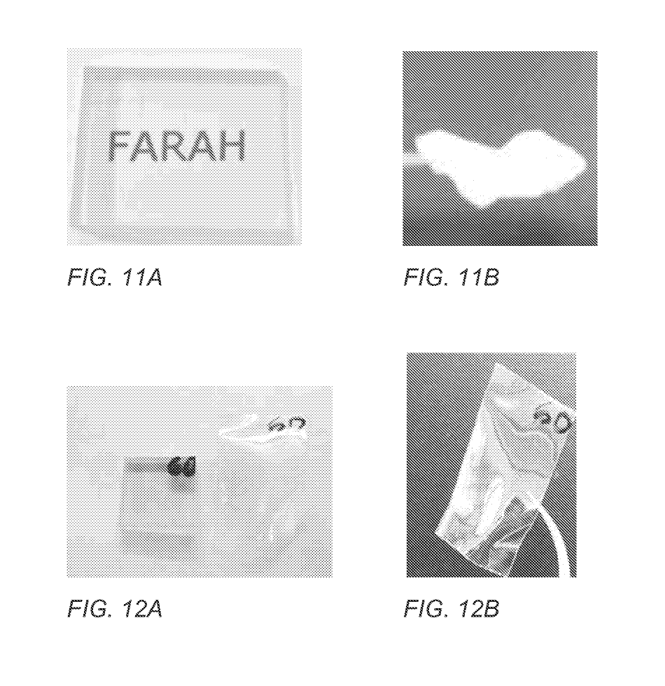

FIG. 11A is an image of the plasma treated SHC-PC material showing that no hazing or conformal shrinkage of the plasma treated SHC-PC material is seen after being subjected to immersion in acetone, methanol, and ethanol. Conversely, total structural collapse of non-plasma treated and non-SHC coated PC material was observed when immersed in acetone as shown in the image shown in FIG. 11B.

FIG. 12A is an image showing that no shrinkage or expansion of the plasma treated SHC-PC material of the present invention at temperatures of 60° C. and 120° C., respectively. Conversely, total structural collapse of non-plasma treated and non-SHC coated PC material was observed at a temperature of 60° C. is depicted in the image shown in FIG. 12B.

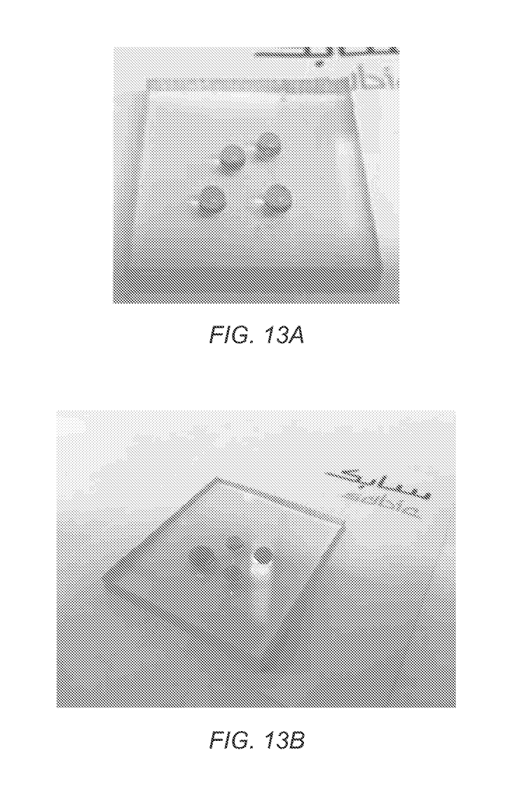

To demonstrate the super-hydrophobic properties of the SHC-PC plasma treated according to the present invention, droplets of water were sprinkled on the top of a sample of the plasma treated SHC-PC material of the present invention (mean water angle 168 degree. See FIG. 5) and a comparative sample of untreated SHC-PC material (mean water angle 82 degree, See FIG. 3). FIG. 13A is an image of the water beading on the surface of the plasma treated SHC-PC material. FIG. 13B is an image of the water beading on the surface of the untreated SHC-PC material. Comparing the beading of the water in the two images, the plasma treated SHC-PC has more rounded and taller beads of water than the untreated SHC-PC material. Thus, the plasma treated SHC-PC material of the present invention has super-hydrophobic properties.

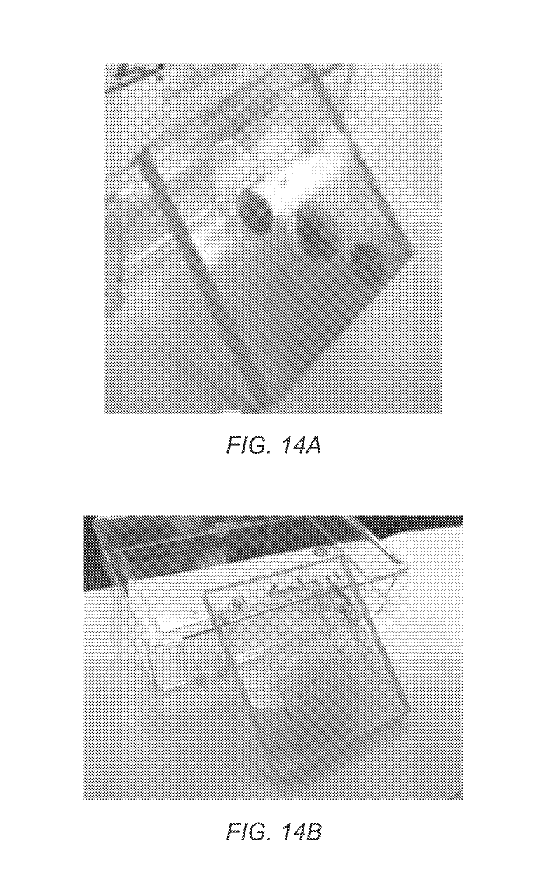

To demonstrate the self-cleaning properties of the SHC-PC plasma treated according to the present invention, dust and water droplets were sprinkled on the surface of a sample of the plasma treated SHC-PC material of the present invention and a comparative sample of untreated SHC-PC material. FIG. 14A is an image of the dust being removed from the surface of the plasma treated SHC-PC material of the present invention. FIG. 14B is an image of dust and water droplets were sprinkled on the surface of a sample of an untreated SHC-PC material. In FIG. 14A, the water droplets on the plasma treated SHC-PC material are collecting the dust while moving down the surface of the plasma treated SHC-PC material. In contrast, the water droplets on the untreated SHC-PC material in FIG. 14 are not collecting the dust particles. Thus, the plasma treated SHC-PC material of the present invention, as demonstrated by the ability to remove the dust, has self-cleaning properties.

1. An optically transparent super-hydrophobic material comprising an optically transparent polymeric layer having a first surface and an opposing second surface, wherein at least a portion of the first surface has been plasma-treated with oxygen and a fluorine containing compound, wherein the treated surface includes:
(i) nano- or micro-structures that are etched into the first surface and that are chemically modified with the fluorine containing compound, wherein the nano- or micro-structures have a height to width aspect ratio of greater than 1; and
(ii) a water contact angle of at least 150°,
wherein the optically transparent polymeric layer retains its optical transparency after said plasma-treatment.

2. The optically transparent material of claim 1, wherein the polymeric layer comprises a polycarbonate or a blend thereof.

3. The optically transparent material of claim 1, wherein the at least a portion of the first surface comprises a functional coating, and wherein the functional coating retains its functional properties after said plasma-treatment.

4. The optically transparent material of claim 3, wherein the functional coating is a silicone hard-coat.

5. The optically transparent material of claim 3, wherein the functional coating is capable of absorbing ultra-violet (UV) light, and wherein the functional coating retains its ability to absorb UV light after said plasma-treatment.

6. The optically transparent material of claim 1, wherein the fluorine containing compound is an organofluorine.

7. The optically transparent material of claim 6, wherein the organofluorine is a fluorocarbon.

8. The optically transparent material of claim 7, wherein the fluorocarbon is CF₄, C₂F₄, C₂F₆, C₃F₆, C₄F₈, or any combination thereof.

9. (canceled)

10. The optically transparent material of claim 1, wherein the at least a portion of the first surface has been plasma treated with a first plasma comprising oxygen followed by a second plasma comprising the fluorine containing compound.

11. (canceled)

12. (canceled)

13. The optically transparent material of claim 1, wherein the polymeric layer comprises a polyethylene terephthalate, a polyolefin, a polystyrene, a poly(methyl)methacrylate, a polyacrylonitrile, a poly(vinylacetate), a poly(vinyl alcohol), a chlorine-containing polymer, a polyoxymethylene, a polyamide, a polyimide, a polyurethane, an amino-epoxy resin, or a polyester, or combinations or blends thereof.

14. (canceled)

15. The optically transparent material of claim 1, wherein the material is disposed on an article of manufacture.

16. The optically transparent material of claim 15, wherein the article of manufacture is a photovoltaic cell or a solar panel.

17-23. (canceled)

24. The optically transparent material of claim 1, wherein the polymeric layer does not include an inorganic compound.

25. (canceled)

26. A method of preparing the optically transparent super-hydrophobic material of claim 1, the method comprising:
(a) obtaining an optically transparent polymeric layer having a first surface and an opposing second surface, wherein the first surface has a water contact angle of less than 150°;
(b) subjecting at least a portion of the first surface of the polymeric layer to a first plasma comprising oxygen under reaction conditions sufficient to obtain nano- or micro-structures that are etched into the polymeric layer, wherein the nano- or micro-structures have a height to width aspect ratio of greater than 1; and
(c) subjecting the treated surface from (b) to a second plasma comprising a fluorine containing compound under reaction conditions sufficient to chemically modify the nano- or micro-structures with the fluorine containing compound,
wherein the treated surface from step (c) has a water contact angle of at least 150°, and
wherein the optically transparent polymeric layer from (a) retains its optical transparency after steps (b) and (c).

27. The method of claim 26, wherein steps (b) and (c) are performed in a continuous process such that the oxygen from step (b) is switched to the fluorine containing compound from step (c) without stopping the process.

28. The method of claim 26, wherein the polymeric layer comprises a polycarbonate or a blend thereof.

29. The method of claim 26, wherein the at least a portion of the first surface in step (b) comprises a functional coating, and wherein the functional coating retains its abrasion resistant properties after steps (b) and (c).

30. The method of claim 29, wherein the functional coating is a silicone hard-coat.

31-43. (canceled)

44. A method of protecting a substrate or article of manufacture from soiling, the method comprising disposing the optically transparent super-hydrophobic material of claim 1 onto a substrate or article of manufacture, wherein the super-hydrophobic material protects the substrate or article of manufacture from soiling.

45. (canceled)

46. (canceled)

47. (canceled)

48. (canceled)

49. A method of maintaining or increasing the efficiency of a photovoltaic cell or protecting the outermost surface of a photovoltaic cell from soiling, the method comprising disposing the optically transparent super-hydrophobic material of claim 1 onto the outermost surface of the photovoltaic cell, wherein the efficiency of the photovoltaic cell is maintained or increased by protecting the outermost surface of the photovoltaic cell from soiling.

50. (canceled)

51. (canceled)
